(19) United States
(12) Patent Application Publication
(10) Pub. No.: US 2025/0343374 A1
(43) Pub. Date: Nov. 6, 2025

(54) INTERFACE CARD POSITIONING FASTENER WITH ELASTIC PUSH ASSISTANCE

(71) Applicant: HANWIT PRECISION INDUSTRIES LTD., New Taipei City (TW)

(72) Inventors: Ying-Chih TSENG, New Taipei City (TW); Ming-De WU, New Taipei City (TW)

(21) Appl. No.: 18/653,124

(22) Filed: May 2, 2024

(51) Int. Cl. H01R 13/627; H01R 12/73; H01R 13/635; H05K 1/18

(52) U.S. Cl. CPC H01R 13/6275; H01R 13/635; H05K 1/18; H01R 12/73; H05K 2201/10189; H05K 2201/10409

(57) ABSTRACT

An interface card positioning fastener with elastic push assistance includes a base with a receiving slot and a storage slot inside, a locking mechanism installed in the receiving slot and having a latching member corresponding to the board edge of an interface card for locking, and a lifting mechanism installed in the storage slot and having a pushing block capable of elastically pushing the board edge of the interface card upward after the latching member and the board edge of the interface card are unlocked so that the preset interface card can form an upward tilt state to facilitate smooth removal of the interface card.

### BACKGROUND OF THE INVENTION

### 1. Field of the Invention

The invention provides an interface card positioning fastener with elastic push assistance, especially the latching member of the positioning fastener is unlocked in the horizontal direction, the pushing block will not be suppressed by the blocking structure of the latching member and the preset interface card and will be elastically reset upward through the compressed longitudinal elastic member located on the bottom side of the pushing block, and the top surface of the pushing block can then resist the bottom side of the preset interface card board edge and move upward, and overcome the weight of the fin heat sinks on both sides of the preset interface card, allowing smooth movement, so that the preset interface card can form an upward tilt state to facilitate smooth removal of the preset interface card.

### 2. Description of the Related Art

The rapid development of the electronics industry has doubled the computing performance of computers and servers. In addition to the main components of the computer including the motherboard, central processing unit, memory and storage devices, the motherboard is also equipped with a variety of connectors with different interfaces to expand various peripheral devices. Expanding various peripheral devices uses interface cards equipped with multiple electronic components and corresponding circuit layouts, and their terminals are presented with multiple metal contacts. By inserting the interface card into the connector on the motherboard, the two devices can be electrically connected to expand the functions of the motherboard.

General mobile electronic devices (such as notebook computers) are limited by the small internal space and cannot arrange various components as generously as a personal computer, in particular, the space for installing the motherboard and related components inside the C and D sides of the notebook computer case is limited by the thickness, and the motherboard and interface card cannot be assembled vertically like a personal computer. Therefore, the assembly of the motherboard and interface card inside the notebook computer must be assembled horizontally through a steering connector. When one end of the interface card is inserted into the steering connector, the other end of the interface card is in a suspended state. The suspended interface card end is usually locked and positioned in the motherboard with a screw to form a stable and unshakable state. However, this screw locking structure is not conducive to the removal of the interface card. When metal screws become loose during the disassembly process or are subject to external vibration and accidentally fall onto the motherboard, it may cause a short circuit on the motherboard, resulting in damage to electronic components. In addition, the screw locking structure must be unlocked using hand tools (such as a screwdriver), which is inconvenient.

Furthermore, some interface cards are equipped with high-speed computing memory chips on both sides. If the necessary heat dissipation structure for the memory chip is not provided when the interface card is in operation, high temperature crashes may occur. Therefore, most manufacturers choose to install fin-type heat sinks on the surface of the double-sided memory chip of the interface card to solve the heat dissipation problem. However, the weight of the interface card plus the two heat sinks often exceeds the elastic restoring force provided by the conductive terminals inside the steering connector, so the interface card cannot bounce upward after the positioning fastener is unlocked, making it impossible to successfully remove the interface card. The aforementioned deficiencies need to be addressed through research and development by those engaged in this industry.

### SUMMARY OF THE INVENTION

Therefore, in view of the above-mentioned problems and deficiencies, the inventor collected relevant information, and after multiple evaluations and considerations, he designed the invention of this positioning fastener for the interface card.

It is the main object of the present invention to provide an interface card positioning fastener with elastic push assistance, which comprises a base comprising a receiving slot and a storage slot inside, a locking mechanism installed in the receiving slot and comprising a latching member corresponding to a board edge of a preset interface card for locking, and a lifting mechanism installed in the storage slot and comprising a pushing block capable of elastically pushing the board edge of the preset interface card upward after the latching member and the board edge of the preset interface card are unlocked. After the latching member is unlocked in the horizontal direction, the pushing block is not suppressed by the blocking structure of the latching member and the preset interface card and can be elastically reset upward through the longitudinal elastic member in the compressed state on the bottom side of the pushing block. The top surface of the pushing block can then resist the bottom side of the board edge of the preset interface card and move upward to overcome the weight of the fin heat sinks on both sides of the preset interface card, allowing smooth movement, so that the preset interface card can form an upward tilt state to facilitate smooth removal of the preset interface card.

Another object of the present invention is that the main body of the latching member comprises two shaft holes respectively located on both sides for a sliding shaft to penetrate and position; the two side panels of the receiving slot of the base are respectively provided with a transverse slideway for the two opposite positioning ends of the sliding shaft to penetrate respectively, and a top surface is formed on the top side of each of the side panels for the sliding surface of the bottom side of the latching member to contact and slide.

Still another object of the present invention is that the back side of the main body of the latching member has a receiving chamber for receiving one end of the transverse elastic member, the other end of the transverse elastic member is against the blocking wall behind the receiving slot of the base, and the transverse elastic member is composed of a spring.

Still another object of the present invention is that the lifting mechanism further comprises a pushing block and a longitudinal elastic member, which is a spring, installed on the bottom protrusion of the bottom side of the pushing block, and there is a guide block that has a structure that is wide at the top and narrow at the bottom protruding from each of both sides of the pushing block; Each of the two opposite inner walls of the base is provided with a guide inclined portion on the top side of the storage slot, and a longitudinal slideway is formed below each of the two guide inclined portions for the two guide blocks to penetrate and position, and the longitudinal slideway also has a structure that is wide at the top and narrow at the bottom.

Still another object of the present invention is that a blocking platform is formed on the top side of the pushing block, and the two front sides of the blocking platform are provided with resisting portions that can push the board edge of the preset interface card; a blocking groove is formed behind the blocking platform, which is shaped like a descending step, and can be used to resist the semicircular positioning body at the bottom surface of the push portion of the latching member, and the blocking groove is also a semicircular groove.

### BRIEF DESCRIPTION OF THE DRAWINGS

FIG. 1 is a three-dimensional appearance view of the positioning fastener of the present invention.

FIG. 2 is a three-dimensional exploded view of the positioning fastener of the present invention.

FIG. 3 is another three-dimensional exploded view of the positioning fastener of the present invention.

FIG. 4 is an elevational view of the interface card of the present invention locked in the positioning fastener.

FIG. 5 is a side cross-sectional view of the interface card of the present invention locked in the positioning fastener.

FIG. 6 is a side cross-sectional view of the interface card of the present invention unlocked from the positioning fastener.

FIG. 7 is a three-dimensional view of the interface card of the present invention unlocked from the positioning fastener.

### DETAILED DESCRIPTION OF THE INVENTION

In order to achieve the above objects and effects, the technical means and structures adopted by the present invention are described in detail below with respect to the preferred embodiment of the present invention, so as to facilitate a complete understanding.

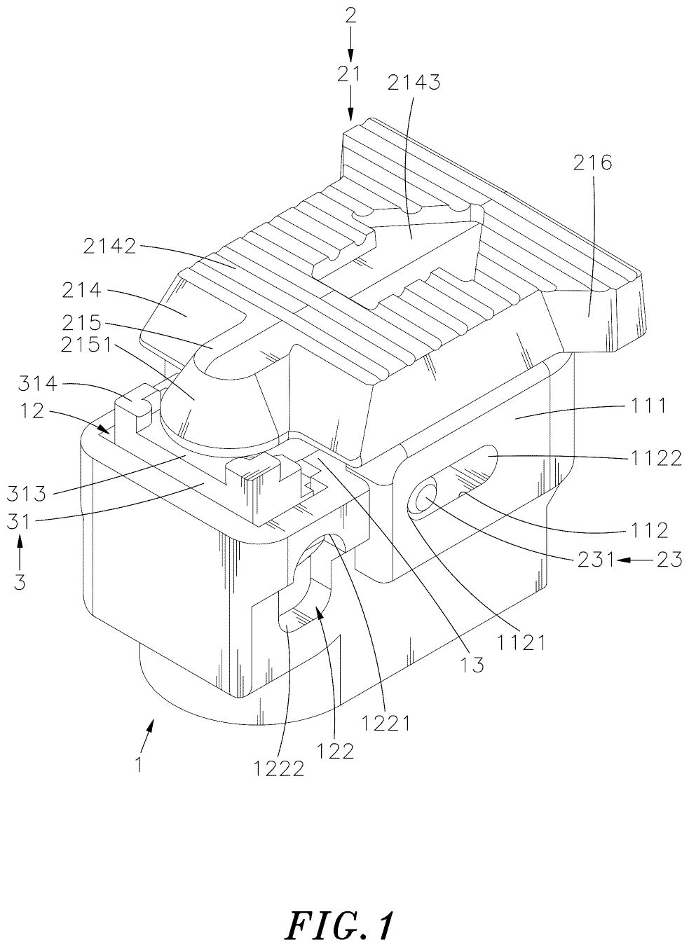

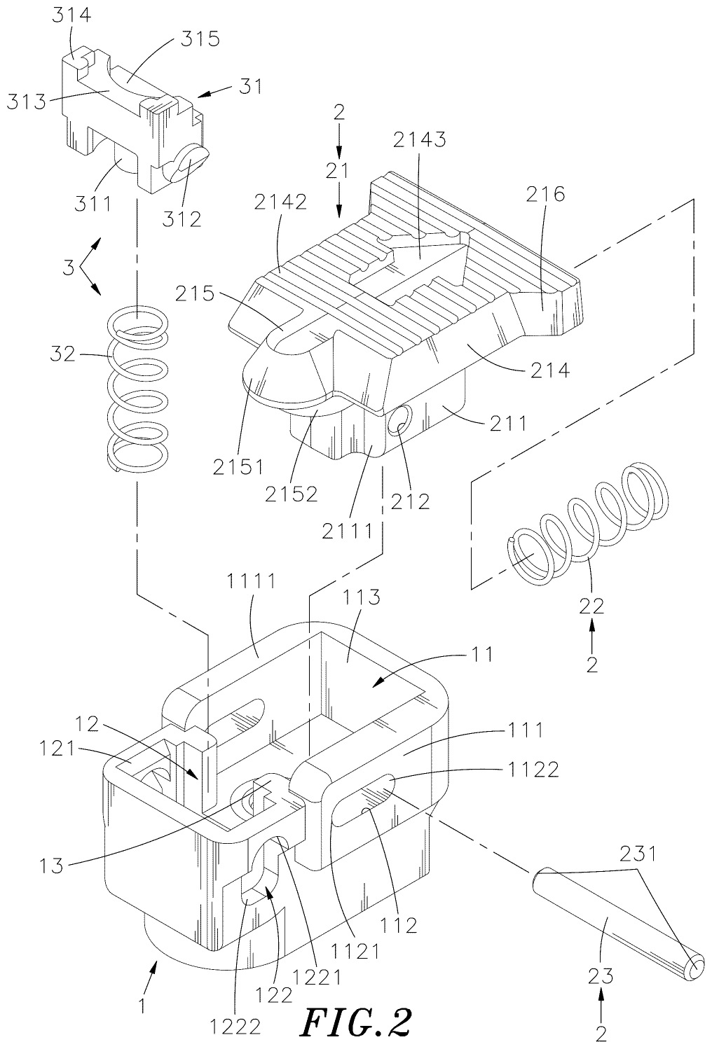

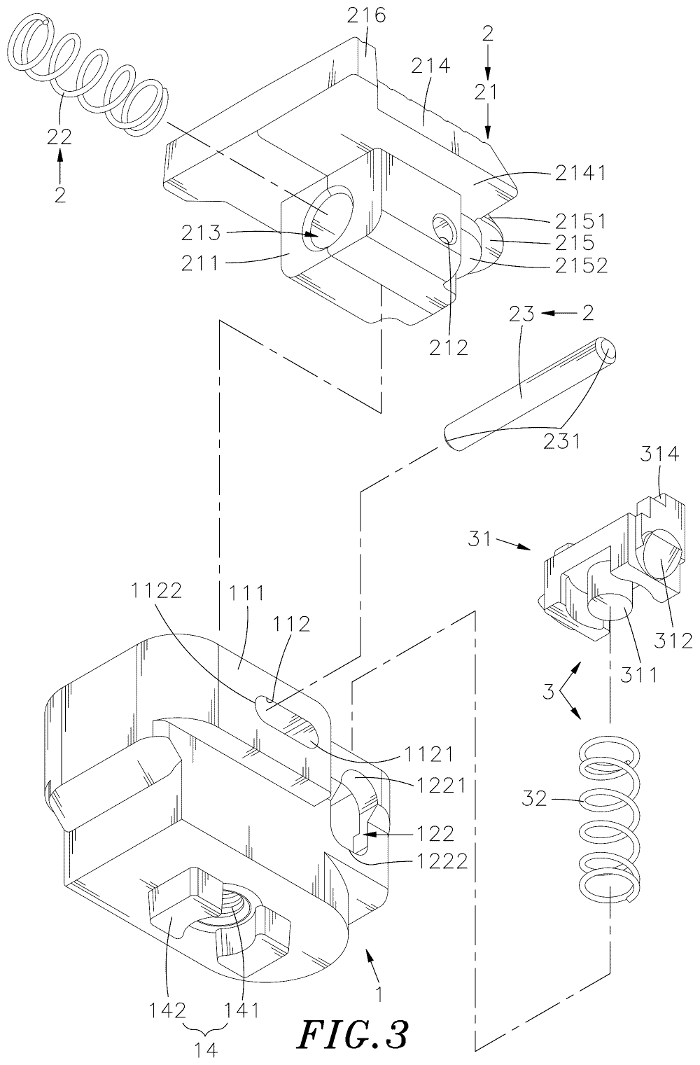

Please refer to FIGS. 1 to 4, which are three-dimensional appearance view of the positioning fastener of the present invention, three-dimensional exploded view of the positioning fastener of the present invention, another three-dimensional exploded view of the positioning fastener of the present invention and an elevational view of the interface card of the present invention locked in the positioning fastener. It can be clearly seen from the drawings that the interface card positioning fastener with elastic push assistance of the present invention comprises: a base 1, a locking mechanism 2 and a lifting mechanism 3. Its main components and features are detailed as follows:

The base 1 is provided with a receiving slot 11 and a storage slot 12 inside.

The locking mechanism 2 is installed in the receiving slot 11. The locking mechanism 2 comprises: a latching member 21 corresponding to the board edge of a preset interface card 42 for locking.

The lifting mechanism 3 is installed in the storage slot 12. After the latching member 21 and the board edge of the preset interface card 42 are unlocked, the pushing block 31 of the lifting mechanism 3 elastically pushes the board edge of the preset interface card 42 upward.

The base 1 further comprises two opposing limiting walls 13 formed between the receiving slot 11 and the storage slot 12, and the two limiting walls 13 serve as a limiting position for the front side walls 2111 formed by concavities on two sides in front of the main body 211 of the latching member 21. The base 1 further comprises a fixing unit 14 formed on the bottom side and fixed to a preset circuit board 4. The fixing unit 14 is provided with a screw groove 141 communicating with the receiving slot 11, and a plurality of spacers 142 protrude downward from the outer edge of the screw groove 141 on the bottom side of the base 1. The screw groove 141 is used for a fastener made of screw to lock the positioning fastener in a fixing hole (not shown) of the preset circuit board 4.

The two sides of the main body 211 of the latching member 21 are respective provided with a shaft hole 212 for a sliding shaft 23 to penetrate and position. The two side panels 111 of the receiving slot 11 of the base 1 are each formed with a transverse slideway 112 for the two positioning ends 231 of the sliding shaft 23 to penetrate and position. A top surface 1111 for a sliding surface 2141 of the latching member 21 to slide is formed on the top side of each side panel 111. The main body 211 of the latching member 21 has a receiving chamber 213 for receiving one end of a transverse elastic member 22. The other end of the transverse elastic member 22 resists a blocking wall 113 on the rear side of the receiving slot 11 of the base 1, and the transverse elastic member 22 is composed of a spring.

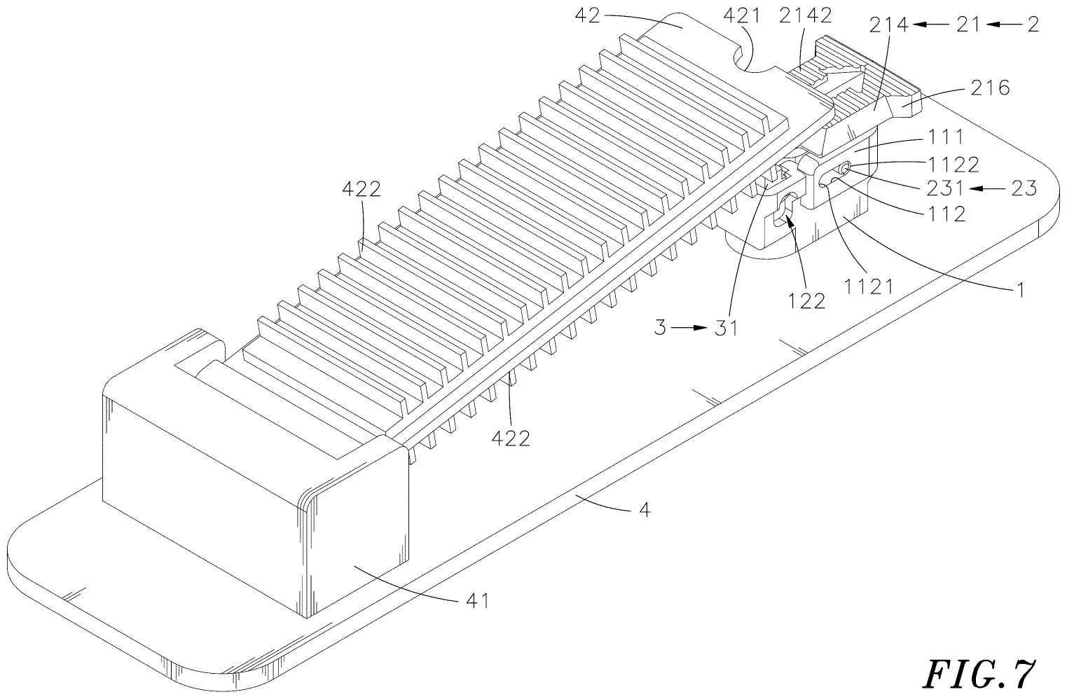

The above-mentioned main body 211 of the latching member 21 has a plate member 214 on the top side. A push portion 215 protrudes from the front of the plate member 214 and a guide slope 2151 is formed on the front side of the push portion 215. The bottom surface of the push portion 215 is further provided with a semicircular plate-shaped positioning body 2152 for resisting and positioning by a positioning groove 421 (as shown in FIG. 7) located on the board edge of the preset interface card 42. An operating portion 216 is formed at the rear of the plate member 214 and expands to both sides. A plurality of tooth-like structures 2142 and an indication pattern 2143 indicating the unlocking direction are provided on the top surface of the plate member 214.

The above-mentioned lifting mechanism 3 further comprises a pushing block 31 and a longitudinal elastic member 32 installed on a bottom protrusion 311 of the pushing block 31. A guide block 312 is respectively protruding from each of two sides of the pushing block 31, and the guide block 312 has a structure that is wide at the top and narrow at the bottom. The two opposite inner walls of the storage slot 12 of the base 1 are each provided with a guide inclined portion 121 on the top side. A longitudinal slideway 122 is respectively formed below each of the two guide inclined portions 121 for the two guide blocks 312 to penetrate and position respectively. The longitudinal slideway 122 also presents a structure that is wide at the top and narrow at the bottom. The longitudinal elastic member 32 is composed of a spring. A blocking platform 313 is formed on the top side of the pushing block 31. Two resisting portions 314 are bilaterally protruding from the front side of the blocking platform 313 and used for pushing the board edge of the preset interface card 42. A blocking groove 315 is formed at the rear side of the blocking platform 313, which is in the shape of a descending step and can be resisted by the semicircular positioning body 2152 at the bottom of the push portion 215 of the latching member 21. The blocking groove 315 is also a semicircular groove.

When assembling the present invention, the longitudinal elastic member 32 is first placed outside the bottom protrusion 311 on the bottom side of the pushing block 31 to complete the assembly of the lifting mechanism 3, and then the lifting mechanism 3 is inserted into the storage slot 12 of the base 1 from top to bottom and the lower end of the longitudinal elastic member 32 is stopped against the bottom side of the storage slot 12, and the guide blocks 312 on both sides of the pushing block 31 are in contact the respective guide inclined portions 121 and sliding downward into the respective longitudinal slideways 122 to form a position. Then, one end of the transverse elastic member 22 is inserted into the receiving chamber 213 of the latching member 21 to force the transverse elastic member 22 into a compressed state, and then the main body 211 of the latching member 21 is inserted into the receiving slot 11. At the same time, the arc-shaped front edge of the push portion 215 of the latching member 21 is pressed between the two resisting portions 314 of the pushing block 31, and the positioning body 2152 located on the bottom of the push portion 215 is pressed against the blocking groove 315 of the pushing block 31 to form positioning. Then align the shaft holes 212 of the latching member 21 with the two transverse slideways 112 of the base 1, and then insert the sliding shaft 23 through the two transverse slideways 112 and the two shaft holes 212, and the two positioning ends 231 of the sliding shaft 23 are positioned in the two transverse slideways 112. Through the above, the assembly of the positioning fastener is completed.

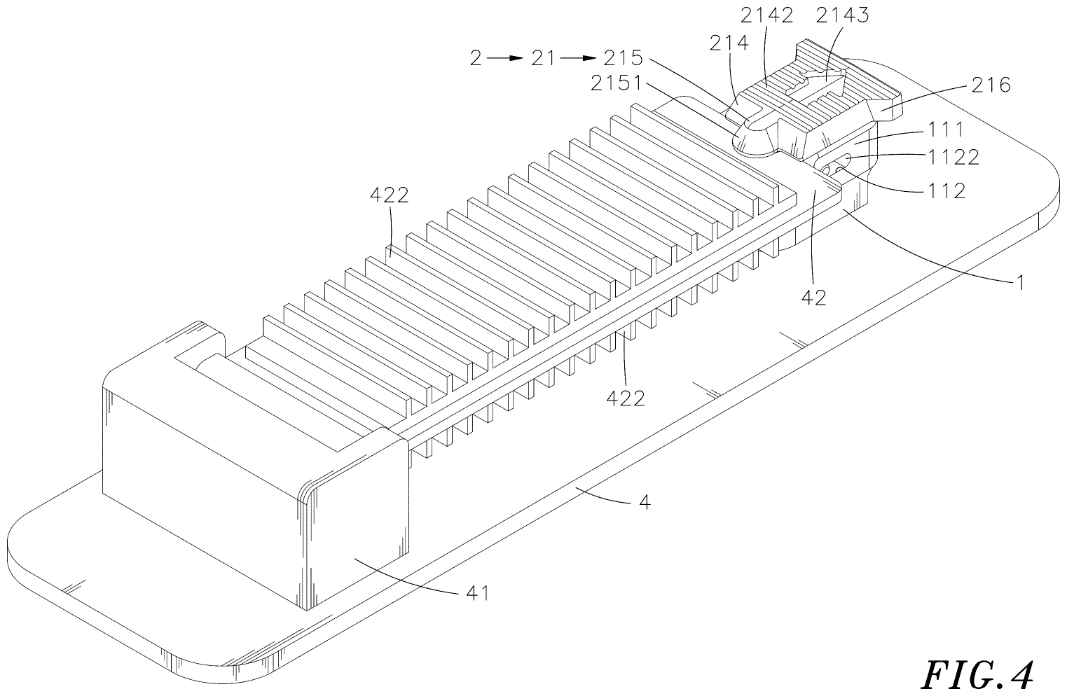

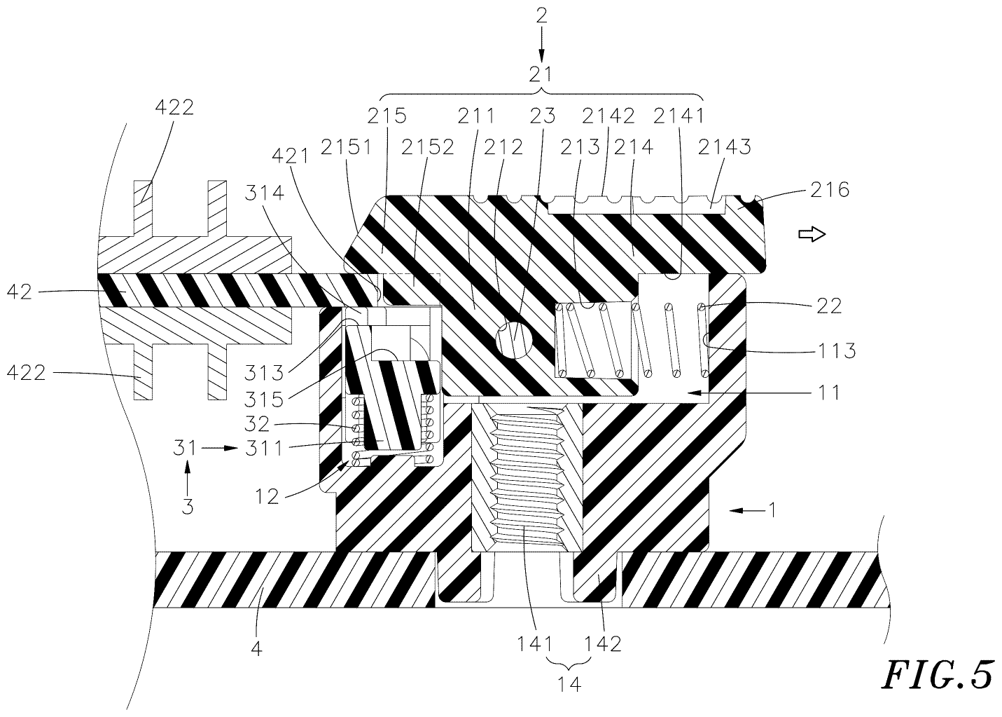

Please refer to FIGS. 4 and 5, which are elevational view of the interface card of the present invention locked in the positioning fastener and side cross-sectional view of the interface card of the present invention locked in the positioning fastener. The circuit board 4 is provided with an electrical connector 41 with an internal oblique docking space (not shown). The interface card 42 composed of an m.2 specification solid state drive (SSD) is inserted obliquely into the docking space of the electrical connector 41 and is electrically connected to a plurality of conductive terminals (not shown). The positioning fastener needs to be used to fix the suspended board edge of the interface card 42. When the suspended board edge of the interface card 42 is to be positioned in the positioning fastener, the electrical connector 41 must be used as the rotation axis, and the interface card 42 must be rotated toward the push portion 215 of the latching member 21. Thus, the push portion 215 is stressed by the interface card 42 in the horizontal direction and retracts, and drives the sliding shaft 23 to move in the two transverse slideways 112 toward the rear side of the base 1 (the sliding shaft 23 moves from the front stop point 1121 to the rear stop point 1122, and causes the transverse elastic member 22 to produce compression deformation), so that the interface card 42 is screwed vertically downward into the positioning body 2152 on the bottom side of the push portion 215, and the positioning groove 421 of the interface card 42 and the positioning body 2152 are positioned against each other (the two guide blocks 312 of the pushing block 31 move from the upper stop point 1221 to the lower stop point 1222, and causes the longitudinal elastic member 32 to produce compression deformation). Thus, the pushing force of the interface card 42 is released from the latching member 21, causing the transverse elastic member 22 and the longitudinal elastic member 32 to generate elastic restoring force that drives the push portion 215, the transverse elastic member 22, the sliding shaft 23, the pushing block 31 and the longitudinal elastic member 32 all to return to their original positions, so that the top surface of the interface card 42 is limited by the push portion 215 of the latching member 21, and the bottom surface of the interface card 42 is positioned by the upward resisting force of the resisting portions 314 of the pushing block 31.

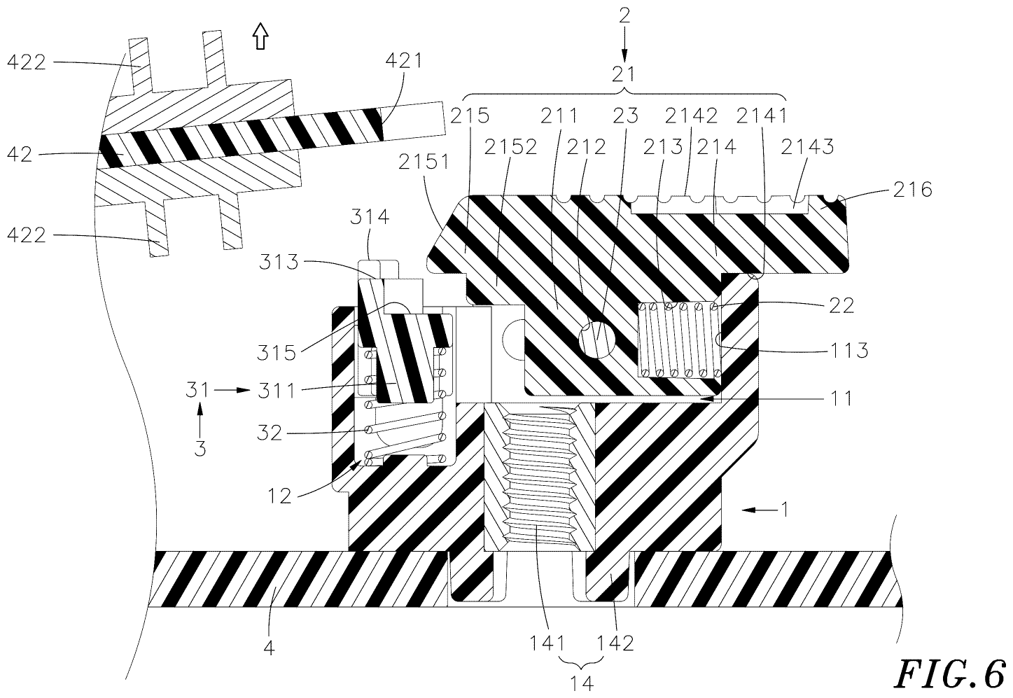

Please refer to FIGS. 6 and 7, which are side cross-sectional view of the interface card of the present invention unlocked from the positioning fastener and three-dimensional view of the interface card of the present invention unlocked from the positioning fastener. When disassembling the positioning fastener and the interface card 42, first apply force on the operating portion 216 of the latching member 21 toward the rear side of the base 1, so that the sliding shaft 23 moves a predetermined distance in the transverse slideways 112, the transverse elastic member 22 produces a great amount of compression, and the sliding surface 2141 on the bottom side of the plate member 214 slides toward the rear side of the base 1 along the top surfaces 1111 of the two side panels 111. At this time, the interface card 42 is subjected to the elastic restoring force of the conductive terminal inside the electrical connector 41, the compressed longitudinal elastic member 32 on the bottom side of the pushing block 31 provides an auxiliary force for elastic reset upwards, and the resisting portions 314 of the pushing block 31 contact the bottom side of the board edge of the interface card 42 and move upward, and can overcome the weight of the fin heat sinks 422 on both sides of the interface card 42 and can move smoothly, so that the board edge of the interface card 42 adjacent to the positioning fastener is turned up. After the positioning groove 421 of the interface card 42 rotates upward and disengages from the push portion 215 of the latching member 21, the interface card 42 can be pulled out from the electrical connector 41 obliquely. Then remove the force on the operating portion 216 of the latching member 21, forcing the push portion 215, the transverse elastic member 22, sliding shaft 23, the pushing block 31 and the longitudinal elastic member 32 to return to their original positions. Through the above, the purpose of separating the positioning fastener and the interface card 42 is achieved.

The main feature of the present invention is that after the latching member 21 of the positioning fastener is unlocked in the horizontal direction, the pushing block 31 is not suppressed by the blocking structure of the latching member 21 and the interface card 42, and an elastic reset can be made upward through the compressed longitudinal elastic member 32 located at the bottom side of the pushing block 31, so that the top surface of the pushing block 31 can resist the bottom side of the board edge of the interface card 42 and push it upward, and overcome the weight of the fin heat sinks 422 installed on both sides of the interface card 42, allowing smooth movement, and the interface card 42 can be tilted upward to facilitate smooth removal of the interface card 42. The present invention is applied in the field of storage modules of electronic devices and has excellent practicability. Therefore, a patent application is filed to seek protection of patent rights.

The above is only a preferred embodiment of the present invention, and does not limit the patent scope of the present invention. Therefore, all simple modifications and equivalent structural changes made by using the contents of the description and drawings of the present invention shall be included in the patent scope of the present invention and shall be clearly stated.

In summary, the above-mentioned interface card positioning fastener with elastic push assistance of the present invention can indeed achieve its effect and purpose when used. Therefore, this invention is truly an invention with excellent practicality. In order to meet the application requirements for an invention patent, I file the application in accordance with the law. I hope that the review committee will approve this case as soon as possible to protect the inventor's hard work on research and development. If the review committee has any doubts, please feel free to send us a letter for instructions. The inventor will do our best to cooperate. We sincerely appreciate it.

What is claimed is:

1. An interface card positioning fastener with elastic push assistance, comprising:
a base comprising a receiving slot and a storage slot inside;
a locking mechanism installed in said receiving slot, said locking mechanism comprising a latching member corresponding to a board edge of a preset interface card for locking; and
a lifting mechanism installed in said storage slot, said lifting mechanism comprising a pushing block capable of elastically pushing the board edge of said preset interface card upward after said latching member and the board edge of said preset interface card are unlocked.

2. The interface card positioning fastener with elastic push assistance as claimed in claim 1, wherein said latching member comprises a main body, a plate member located at a top side of said main body, a sliding surface located on a bottom side of said plate member and two shaft holes respectively located on two opposite sides of said main body; said base further comprises two side panels respectively formed on two opposite sides of said receiving slot and two transverse slideways respectively located on said two side panels of said receiving slot, each said side panel having a top surface provided for said sliding surface of said latching member to contact and slide; said locking mechanism further comprises a sliding shaft having two opposite positioning ends, said sliding shaft being inserted through said shaft holes with said positioning ends respectively slidably positioned in said transverse slideways.

3. The interface card positioning fastener with elastic push assistance as claimed in claim 1, wherein said latching member further comprises a receiving chamber formed in said main body; said base further comprises a blocking wall located at a rear side of said receiving slot; said locking mechanism further comprises a transverse elastic member, said transverse elastic member being a spring having one end thereof positioned in said receiving chamber and an opposite end thereof stopped against said blocking wall.

4. The interface card positioning fastener with elastic push assistance as claimed in claim 1, wherein said latching member comprises a main body, a plate member located at a top side of said main body, a push portion protruding from a front side of said plate member, a guide slope formed on a front side of said push portion and a semicircular plate-shaped positioning body located on a bottom surface of said push portion for resisting and positioning by a positioning groove on the board edge of said interface card.

5. The interface card positioning fastener with elastic push assistance as claimed in claim 4, wherein said latching member further comprises an operating portion formed at a rear side of said plate member and extending to two opposite sides.

6. The interface card positioning fastener with elastic push assistance as claimed in claim 4, wherein said latching member further comprises a plurality of tooth-like structures and an indication pattern located on a top surface of said plate member said indication pattern being used for indicating an unlocking direction.

7. The interface card positioning fastener with elastic push assistance as claimed in claim 1, wherein said base further comprises two limiting walls formed on two opposite sides between said receiving slot and said storage slot; said latching member comprises a main body, and two front side walls recessed on a front side of said main body and respectively stopped against said two limiting walls of said base.

8. The interface card positioning fastener with elastic push assistance as claimed in claim 1, wherein said base further comprises a fixing unit and a plurality of spacers located on a bottom side thereof, said fixing unit being fixed to a preset circuit board and comprising a screw groove in communication with said receiving slot, said spacers protruding downward from an outer edge of said screw groove.

9. The interface card positioning fastener with elastic push assistance as claimed in claim 1, wherein said lifting mechanism comprises a bottom protrusion protruded from a bottom side of said pushing block, a longitudinal elastic member installed on said bottom protrusion, two guide blocks respectively protruding from two sides of said pushing block, each said guide block presenting a structure that is wide at the top and narrow at the bottom, said longitudinal elastic member being a spring; said base further comprises two guide inclined portions respectively formed on two opposite inner walls of said storage slot at a top side, and two longitudinal slideways respectively formed below said two guide inclined portions for said two guide blocks to penetrate and position respectively, said longitudinal slideways also presenting a structure that is wide at the top and narrow at the bottom.

10. The interface card positioning fastener with elastic push assistance as claimed in claim 9, wherein said latching member comprises a main body, a plate member located at a top side of said main body, a push portion protruding from a front side of said plate member, and a semicircular positioning body located at a bottom side of said push portion; said lifting mechanism comprises a blocking platform formed on a top side of said pushing block, two resisting portions bilaterally protruding from a front side of said blocking platform and used for pushing a board edge of an interface card and a blocking groove formed at a rear side of said blocking platform, said blocking groove being in the shape of a descending step to be resisted by said semicircular positioning body of said latching member, said blocking groove being also a semicircular groove.
